(19) United States
(12) Patent Application Publication
(10) Pub. No.: US 2026/0223599 A1
(43) Pub. Date: Jul. 30, 2026

(54) SELF-ALIGNED SPIN-ORBIT TORQUE MRAM

(71) Applicant: International Business Machines Corporation, Armonk, NY (US)

(72) Inventor: Jim Shih-Chun Liang, Poughkeepsie, NY (US)

(21) Appl. No.: 19/040,105

(22) Filed: Jan. 29, 2025

(51) Int. Cl. H10N 50/10; G11C 11/16; H10N 50/85

(52) U.S. Cl. CPC H10N 50/10; G11C 11/161; H10N 50/85

(57) ABSTRACT

A spin-orbit torque magnetoresistive random access memory (SOT MRAM) device having improved SOT efficiency is provided by providing an SOT channel layer that is self-aligned with a size of an active magnetic tunnel junction (MTJ) structure. Notably, and in one embodiment of the present application, the SOT MRAM device includes an active MTJ-containing structure located on a SOT channel layer, wherein the active MTJ-containing structure has a width that is substantially equal to a width of the SOT channel layer.

### BACKGROUND

The present application relates to a memory device, and more particularly to a spin-orbit torque magnetoresistive random access memory (SOT MRAM) device having improved SOT efficiency.

MRAM is a non-volatile random access memory technology in which data is stored by magnetic storage elements. These elements are typically formed from two ferromagnetic plates, each of which can hold a magnetization, separated by a thin dielectric layer (i.e., a tunnel barrier layer). One of the two plates (i.e., the magnetic reference or pinned layer) is a magnet whose magnetic moment direction is set to a particular direction; the other plate's (i.e., the magnetic free layer's) magnetization can be changed in at least two different directions, representing different digital states such as 0 and 1 for memory applications. In MRAMs, such elements may be referred to as a magnetic tunnel junction (MTJ) structure. In a typical MTJ structure, the magnetization of the magnetic reference layer is fixed in one direction (say pointing up), while the direction of the magnetic free layer can be “switched” by some external forces, such as a magnetic field or a spin-torque generating charge current. A smaller current (of either polarity) can be used to read the resistance of the device, which depends on the relative orientations of the magnetizations of the magnetic free layer and the magnetic reference layer. The resistance is typically higher when the magnetizations are anti-parallel, and lower when they are parallel (though this can be reversed, depending on the material).

One type of MRAM device that can use a MTJ structure is spin-transfer torque (STT) MRAM. STT MRAM has the advantages of lower power consumption and better scalability over conventional MRAM which uses magnetic fields to flip the active elements. In STT MRAM, spin-transfer torque is used to flip (switch) the orientation of the magnetic free layer. For an STT MRAM device, a current passing through the MTJ structure is used to switch, or “write” the bit-state of the MTJ memory element. A current passing down through the MTJ structure makes the magnetic free layer parallel to the magnetic reference layer, while a current passed up through the MTJ structure makes the magnetic free layer anti-parallel to the magnetic reference layer.

Another type of MRAM device that can use a MTJ structure is a spin-orbit torque (SOT) MRAM device. SOT memory devices do not require passing of high current through the MTJ structure during the write operation, which is done by a current flowing through a SOT channel layer. SOT MRAM devices are actively being considered as a beyond STT MRAM option for reducing write current and eliminating read disturb.

### SUMMARY

A SOT MRAM device having improved SOT efficiency is provided by providing a SOT channel layer that is self-aligned with a size (i.e., width) of an active magnetic tunnel junction (MTJ)-containing structure.

In one embodiment of the present application, the SOT MRAM device includes an active MTJ-containing structure located on a SOT channel layer, where the active MTJ-containing structure has a width that is substantially equal to a width of the SOT channel layer.

In another embodiment of the present application, the SOT MRAM device includes an interconnect level including at least one electrically conductive structure embedded in an interconnect dielectric layer, a SOT channel layer located above the interconnect level, an active MTJ-containing structure located on the SOT channel layer, where the active MTJ-containing structure has a width that is substantially equal to a width of the SOT channel layer, a passivation liner present along a sidewall of the active MTJ-containing structure and along sidewall of the SOT channel layer, where the passivation liner extends below a bottommost surface of the SOT channel layer and is present on a surface of the interconnect dielectric layer of the interconnect level, and a metal structure in contact with the active MTJ-containing structure.

### BRIEF DESCRIPTION OF THE DRAWINGS

FIG. 1 is a cross sectional view of an exemplary SOT MRAM device in accordance with an embodiment of the present application.

FIG. 2A is a top down view of an exemplary structure after performing a first ion beam etching (IBE) patterning step that can be used in providing the exemplary SOT MRAM device illustrated in FIG. 1, the exemplary structure including an active MTJ-containing structure and surrounding MTJ-containing fill structures located on a SOT channel material layer.

FIG. 2B is a cross sectional view along the X-X cut of the exemplary structure illustrated in FIG. 2A.

FIG. 2C is a cross sectional view along the Y-Y cut of the exemplary structure illustrated in FIG. 2A.

FIG. 3A is a top down view of the exemplary structure shown in FIG. 2A after performing a second IBE patterning step.

FIG. 3B is a cross sectional view along the X-X cut of the exemplary structure illustrated in FIG. 3A.

FIG. 3C is a cross sectional view along the Y-Y cut of the exemplary structure illustrated in FIG. 3A.

FIG. 4A is a top down view of the exemplary structure shown in FIG. 3A after performing a third IBE patterning step.

FIG. 4B is a cross sectional view along the X-X cut of the exemplary structure illustrated in FIG. 4A.

FIG. 4C is a cross sectional view along the Y-Y cut of the exemplary structure illustrated in FIG. 4A.

FIG. 5A is a top down view of the exemplary structure shown in FIG. 4A after performing a fourth IBE patterning step.

FIG. 5B is a cross sectional view along the X-X cut of the exemplary structure illustrated in FIG. 5A.

FIG. 5C is a cross sectional view along the Y-Y cut of the exemplary structure illustrated in FIG. 5A.

FIG. 6A is a cross sectional view of the exemplary structure shown in FIG. 5B after performing a fifth IBE patterning step, forming a passivation liner, and forming a first interlayer dielectric (ILD) layer.

FIG. 6B is a cross sectional view of the exemplary structure shown in FIG. 5C after performing a fifth IBE patterning step, forming a passivation liner, and forming a first interlayer dielectric (ILD) layer.

FIG. 7A is a cross sectional view of the exemplary structure shown in FIG. 6A after forming a metal structure in contact with at least a topmost surface the active MTJ-containing structure.

FIG. 7B is a cross sectional view of the exemplary structure shown in FIG. 6B after forming a metal structure in contact with at least a topmost surface the active MTJ-containing structure.

FIG. 8 is a top down view another exemplary SOT MRAM device in accordance with an embodiment of the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

SOT MRAM devices are only efficient when the SOT channel layer width substantially matches the MTJ-containing structure size. Notably, the spin current to switch the magnetic free layer of the MTJ-containing structure is only maximized when the MTJ-containing structure size is about the same as the SOT channel layer width. Charge current that does not pass directly under the MTJ structure of the MTJ-containing structure can lead to lower SOT efficiency and possible joule heating that can increase thermal instability.

Current methods rely on overlaying two masks to produce the MTJ-containing structure and the SOT channel layer which often leads to one side of the SOT channel layer extending beyond the MTJ-containing structure and on purposely making the SOT channel layer width greater than the MTJ-containing structure size to account for overlay and sidewall encapsulation thickness. Other methods result in a structure that causes the bottom electrode to overlap the MTJ-containing structure resulting in STT effects, less SOT and tight overlay tolerances.

A SOT MRAM device is provided in the present application in which the size (i.e., width) of the MTJ-containing structure (herein also referred to as an active MTJ-containing structure) substantially matches the SOT channel layer width such that the SOT effect is strengthen. In embodiments of the present application, MTJ-containing fill structures can be present that surround the active MTJ-containing structure. These MTJ-containing fill structures are advantageously employed as an on-wafer mask for IBE to pattern a self-aligned MTJ-containing structure to the SOT channel layer. The method that is used in the present application to form the SOT MRAM device having the improved (i.e., “strengthen”) SOT effect reduces the number of necessary masking layers by one, and the number of passivation liners (from two to one) to protect the MTJ-containing structure.

The SOT MRAM device of the present application in which the active MTJ-containing structure is self-aligned to the SOT channel layer has improved write speed and endurance over existing STT MRAM devices. Moreover, the SOT MRAM device of the present application in which the active MTJ-containing structure is self-aligned to the SOT channel layer has maximized spin-current into the magnetic free layer that is present in the MTJ-containing structure for improved writing. The SOT MRAM device of the present application is compatible with any front-end-of-the-line (FEOL) technology such as, for example, planar field effect transistors (FETs), finFETs, and/or gate-all-around (GAA) nanosheet FETs.

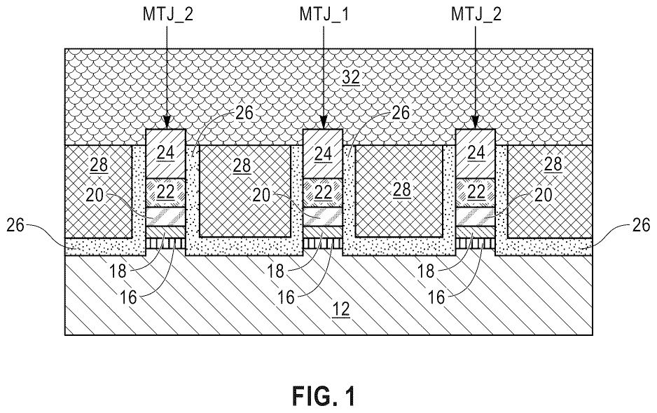

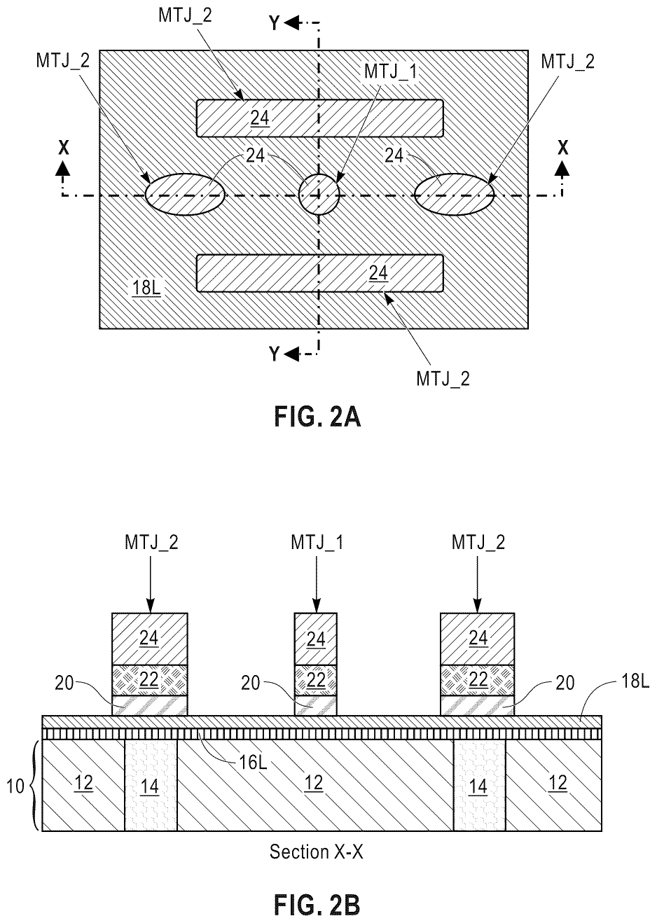

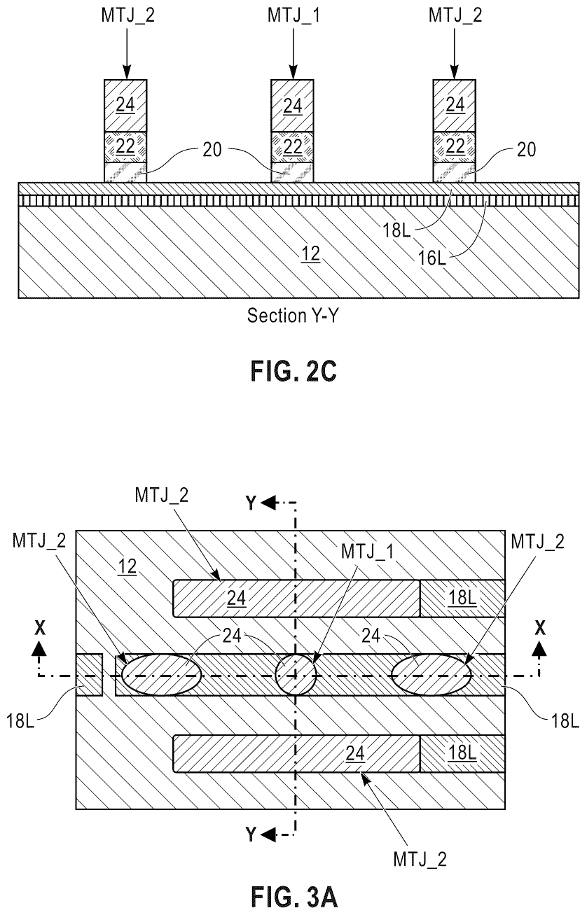

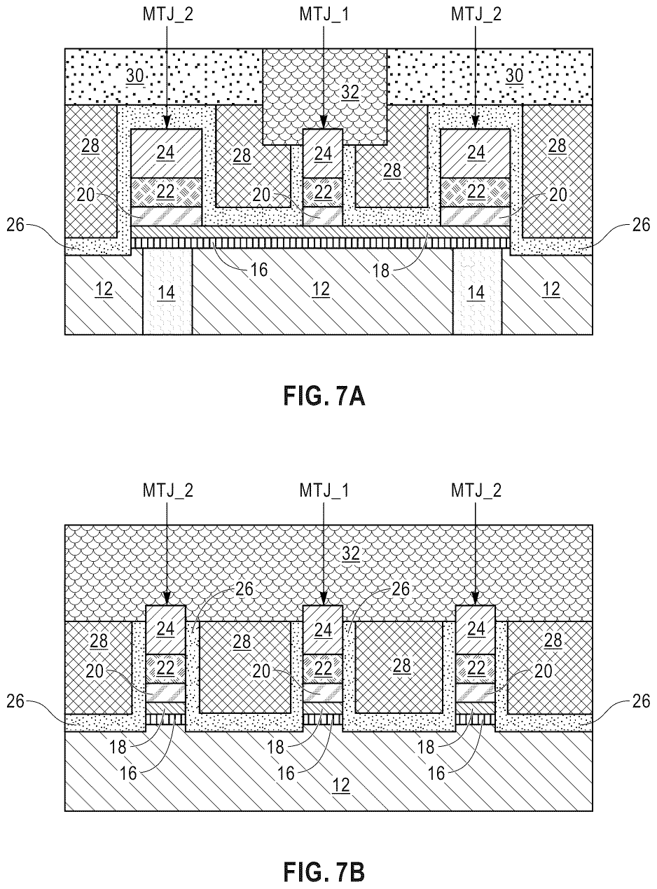

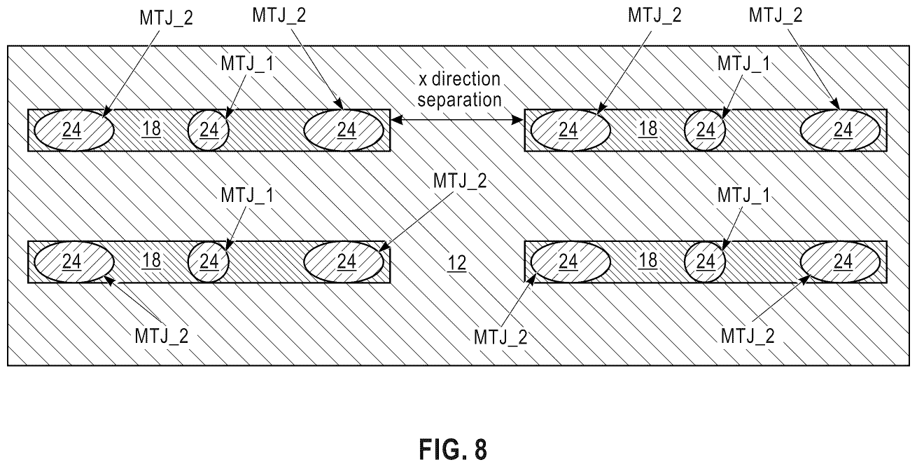

Reference is now made to FIG. 1 which illustrates an exemplary SOT MRAM device in accordance with an embodiment of the present application. The SOT MRAM device illustrated in FIG. 1 is along a Y-Y cut as shown in FIG. 2A. The Y-Y cut is along a Y-direction of the device. In this illustrated embodiment, an active MTJ-containing structure, MTJ_1, is positioned between a pair of MTJ-containing fill structures, each MTJ-containing fill structure is labeled as MTJ_2 in the drawings of the present application. In the present application, each MTJ-containing fill structure, MTJ_2, is a non-active structure which serves as an on device mask. In the present application, each MTJ-containing fill structure, MTJ_2, is designed to have a height that is sufficient to protect the SOT channel layer 18. In the present application, each MTJ-containing fill structure, MTJ_2, is designed to have a width that is thick enough to protect the at least one electrically conductive structure 14 (not shown in the cross sectional view depicted in FIG. 1) that is embedded in interconnect dielectric layer 12. In the present application, a first pair of MTJ-containing fill structures can be present along a Y-Y cut as illustrated in FIG. 1 (and FIG. 7B), while a second pair of MTJ-containing fill structures can be present along an X-X cut (see, for example, FIG. 7A). In some embodiments, which is the case illustrated in FIG. 8, the second pair of MTJ-containing fill structures can be omitted from the SOT MRAM device of the present application.

As is illustrated in FIG. 1, each MTJ-containing fill structure, MTJ_2, and the active MTJ-containing structure, MTJ_1, are located on SOT channel layer 18 that is located on top of interconnect dielectric layer 12 of interconnect level 10 (see, for example, FIG. 2B). Although not shown in the cross sectional view illustrated in FIG. 1, the interconnect dielectric layer 12 can include at least one electrically conductive structure 14 (see, for example, FIG. 2B) embedded therein. In some embodiments and as is illustrated in FIG. 1, a SOT seed layer 16 can be located between the SOT channel layer 18 and the interconnect level 10 including the interconnect dielectric layer 12.

Although not illustrated in FIG. 1, each MTJ-containing fill structure, MTJ_2, and the active MTJ-containing structure, MTJ_1, typically, but not necessarily always, are substantially cylindrical in shape. Each MTJ-containing fill structure, MTJ_2, and the active MTJ-containing structure, MTJ_1, includes a material stack of, from bottom to top, a magnetic material containing stack 20, a metal cap 22 and a metal-containing hard mask 24. It is noted that the magnetic material containing stack can also be referred to a MTJ structure. In the cross sectional view shown in FIG. 1, the magnetic material containing stack 20 has an outermost sidewall that is vertically aligned to an outermost sidewall of the metal cap 22 and the metal-containing hard mask 24. Collectively, the metal cap 22 and the metal-containing hard mask 24 can be used as an electrode of each MTJ-containing fill structure, MTJ_2, and the active MTJ-containing structure, MTJ_1. In addition, the active MTJ-containing structure, MTJ_1, is self-aligned to the SOT channel layer 18 such that a width of the active MTJ-containing structure, MTJ_1, substantially matches a width of the SOT channel layer 18 as is illustrated in FIG. 1. This feature of the present application (i.e., self-alignment of the active MTJ-containing structure, MTJ_1, to the SOT channel layer 18) provides the SOT MRAM device of the present application with a strengthen SOT effect (i.e., improved SOT efficiency).

As is shown in FIG. 1, a passivation liner 26 is located along the sidewall of each MTJ-containing fill structure, MTJ_2, and the sidewall of the active MTJ-containing structure, MTJ_1. In the cross sectional view illustrated in FIG. 1, the passivation liner 26 is also present along a sidewall of the SOT channel layer 18 and, if present, a sidewall of the SOT seed layer 16. As is illustrated in FIG. 1, the passivation liner 26 extends below a bottommost surface of the SOT channel layer 18 and, if present, below a bottommost surface of the SOT seed layer 16. The passivation liner 26 extends onto a sub-surface (i.e., a surface that is located between a topmost surface of a material and a bottommost surface of the material) of the interconnect dielectric layer 12. Unlike prior art SOT MRAM, only a single passivation liner is employed in the present application.

As is further shown in FIG. 1, a metal structure 32 can be in contact with at least a topmost surface of the active MTJ-containing structure, MTJ_1; in the cross sectional view illustrated in FIG. 1, the metal structure 32 is also in contact with a topmost surface of each MTJ-containing fill structure MTJ_2. The metal structure 32 can be an interconnect structure such as, for example, a metal line (as is illustrated in the drawings of the present application), a metal via or combined metal line and metal via, or a contact structure.

The various elements/components of the SOT MRAM device illustrated in FIG. 1 will be described in greater detail in FIGS. 2A-7B which drawings illustrate basic processing steps that can be used in the present application in forming the SOT MRAM having the improved (i.e., enhanced) SOT efficiency. Notably, FIGS. 2A-2B illustrate a first processing step of the method which can be used in providing a SOT MRAM device such as, for example, the SOT MRAM device illustrated in FIG. 1. Notably, FIG. 2A illustrates an exemplary structure after performing a first IBE patterning step. The exemplary structure illustrated in FIG. 2A includes active MTJ-containing structure, MTJ_1, and MTJ-containing fill structures, MTJ_2, which surround the active MTJ-containing structure, MTJ_1. FIG. 2B is a cross sectional view along the X-X cut of the exemplary structure illustrated in FIG. 2A, while FIG. 2C is a cross sectional view along the Y-Y cut of the exemplary structure illustrated in FIG. 2A. As illustrated in FIG. 2A, the X-X cut is along an X-direction, and the Y-Y cut is along a Y-direction. The X direction is along a length wise direction of the SOT channel layer 18, and the Y direction is along a width wise direction of the SOT channel layer 18.

The exemplary structure illustrated in FIGS. 2A-2C includes interconnect level 10 located beneath each MTJ-containing fill structure, MTJ_2, and the active MTJ-containing structure, MTJ_1. The interconnect level 10 includes at least one electrically conductive structure 14 (two are shown by way of one example in the FIG. 2B of the present application) embedded in interconnect dielectric layer 12. The interconnect level 10 (including the at least one electrically conductive structure 14 and the interconnect dielectric layer 12) can be located above at least one underlying metal level (not shown) and a FEOL level also not shown. In some embodiments, the metal level can be a middle-of-the line (MOL) level. In other embodiments, the metal level can include at least one lower interconnect level of a multi-level interconnect structure. In yet further embodiments, the metal level can be a combination of a MOL level and at least one lower interconnect level of a multi-level interconnect structure. The metal level can include bottom electrically conductive structures embedded in a dielectric material layer. The FEOL level can include a semiconductor substrate having one or more semiconductor devices (such as, for example, transistors) formed thereon. The metal level and the FEOL level can be formed utilizing materials and techniques that are well known to those skilled in the art. So not to obscure the SOT MRAM device of the present application, the materials and techniques used in providing the metal level and the FEOL are not described in the present application.

The interconnect dielectric layer 12 can be composed of any interconnect dielectric material including, for example, silicon oxide (SiOₓ), silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. The interconnect dielectric layer 12 can have a dielectric constant (all dielectric constants mentioned herein are measured relative to a vacuum, unless otherwise stated) that is about 4.0 or less. In one embodiment, the interconnect dielectric layer 12 has a dielectric constant of 2.8 or less. These dielectrics generally having a lower parasitic cross talk as compared to dielectric materials whose dielectric constant is greater than 4.0. The interconnect dielectric layer 12 can be formed by a deposition process such as, for example, chemical vapor deposition (CVD), plasma enhanced chemical vapor deposition (PECVD) or spin-on coating. The interconnect dielectric layer 12 can have a thickness from 50 nm to 250 nm. Other thicknesses that are lesser than 50 nm, and greater than 250 nm can also be employed in the present application as the thickness of the interconnect dielectric layer 12.

The at least one electrically conductive structure 14 can be composed of an electrically conductive metal or electrically conductive metal alloy (collectively the electrically conductive metal or electrically conductive metal alloy can be referred to as an electrically conductive material). Illustrative examples of electrically conductive materials that can be used in the present application to provide that at least one electrically conductive structure 14 include, but are not limited to, Cu, Al, Cu—Al alloy, W, Ru, or Rh. The at least one electrically conductive structure 14 typically, but not necessarily always, is substantially cylindrical in shape.

In some embodiments, a diffusion barrier liner (not shown) can be present along at least a sidewall (and in some embodiments along a bottommost surface) of the at least one electrically conductive structure 14. When present, the diffusion barrier liner can be composed of any well-known diffusion barrier material such as, for example, Ta, TaN, Ti, TiN, W or WN. In some embodiments, the diffusion barrier liner can include a material stack of two or more diffusion barrier materials. In one example, the diffusion barrier liner can be composed of a stack of Ta/TaN or a stack of Ti/TiN.

The interconnect level 10 can be formed by first depositing the interconnect dielectric layer 12. Next, at least one opening is formed into the interconnect dielectric layer 12 by lithography and etching. Lithography includes forming a photoresist material on a surface of a material layer or structure that needs to be patterned, exposing the deposited photoresist material to a pattern of irradiation and thereafter developing the exposed photoresist material. The etching used in providing the at least one opening into the interconnect dielectric layer 12 can include a dry etching process (i.e., reactive ion etching, plasma etching IBE) or a chemical wet etch. Next, and if present, a layer of diffusion barrier material can be formed in the at least one opening and on top of the interconnect dielectric layer 12. The forming of the layer of diffusion barrier material includes a deposition process such as, for example, CVD, PECVD, physical vapor deposition (PVD) or atomic layer deposition (ALD). The layer of diffusion barrier material does not fill in an entirety of the at least one opening. Next, one of the above mentioned electrically conductive materials (e.g., Cu) is then deposited on the layer of diffusion barrier material. The deposition of the electrically conductive material can include CVD, PECVD, PVD, ALD, sputtering or plating. A planarization process such as, for example, chemical mechanical planarization (CMP), is then performed to remove the layer of diffusion barrier material (if the same is present) and the electrically conductive material that is formed outside of the at least one opening and on top of the interconnect dielectric layer 12. The electrically conductive material and, if present, the layer of diffusion barrier material remain in the at least one opening after the planarization process. The electrically conductive material that remains in the at least one opening provides the at least one electrically conductive structure 14 and, if present, the diffusion barrier material layer that remains in the at least one opening provides the diffusion barrier liner (not shown in the drawings of the present application). In embodiments of the present application, the at least one electrically conductive structure 14 has a topmost surface that is substantially coplanar with at least a topmost surface of the interconnect dielectric layer 12; if a diffusion barrier liner is present, the topmost surface of the at least one electrically conductive structure 14 can be substantially coplanar with a topmost surface of the diffusion barrier layer as well as with a topmost surface of the interconnect dielectric layer 12.

The exemplary structure illustrated in, for example, FIGS. 2B and 2C, of the present application includes a SOT channel material layer 18L located on top of the interconnect level 10 (including on top of the at least one electrically conductive structure 14 and the interconnect dielectric layer 12). In some embodiments, the SOT channel material layer 18L is located directly on a surface of the interconnect level 10. In other embodiments, the SOT channel material layer 18L is located on SOT seed material layer 16L. In such an embodiment, the SOT seed material layer 16L is located directly on a surface of the interconnect level 10 and the SOT channel material layer 18L is located directly on a surface of the SOT seed material layer 16L. In the present application, the SOT seed material layer 16L is a precursor layer used in providing the SOT seed layer 16 illustrated in FIG. 1, and the SOT channel material layer 18L is a precursor layer used in providing the SOT channel layer 18 illustrated in FIG. 1.

The SOT seed material layer 16L (which is used in providing the SOT seed layer 16) is composed of a seed material that can facilitate the formation of the SOT channel material layer 18L. Illustrative examples of seed materials that can be used as the SOT seed material layer 16L include, but are not limited to, Ta, TaN, or Ta-containing composite in which a layer of a Ta is present on TaN base layer. The SOT seed material layer 16L is a blanket layer that is present on an entirety of the interconnect level 10. The SOT seed material layer 16L can be formed utilizing a deposition process including, but not limited to, CVD, PECVD, PVD, ALD (including plasma enhanced ALD) or sputtering.

The SOT channel material layer 18L (which is used in providing the SOT channel layer 18) is composed of any spin-conductor material including, for example, β-W, WN, Ta and/or Pt. In some embodiments, the SOT channel material layer is composed of a composite that includes a bi- or multi-layered structure in the form of A/B or A/I/B, where A=β-Ta, β-W, CuₓPt₁₋ₓ, Cu₁₋ₓTaₓ, PdₓPt₁₋ₓ, AuₓPt₁₋ₓ, Pt, Bi₂Se₃, WTe₂, PtTe₂, TaS₂, PtₓRh₁₋ₓ or any materials known to produce large SOT charge-to-spin conversion efficiency, x is from 0 to 1; and B=Cu, Ag, Au . . . are known good spin-conductors, and with ‘I’ as a poor charge-conductor, but good spin-conductor such as NiO, FeOx, and other magnon-mediated spin-conducting, but charge insulating, ferro-ferri- or antiferro-magnetic materials. The I-layer in this case is used as an interface layer between A and B to facilitate spin-conduction but prevent charge-current shunting. The SOT channel material layer 18L is a blanket layer that is present on an entirety of SOT seed material layer 16L (when the same is present) or an entirety of the interconnect level 10, if the SOT seed material layer 16L is not present. The SOT channel material layer 18L can be formed utilizing a deposition process including, but not limited to, CVD, PECVD, PVD, ALD (including plasma enhanced ALD) or sputtering.

As stated above, each MTJ-containing fill structure, MTJ_2, and the active MTJ-containing structure, MTJ_1, includes a material stack of, from bottom to top, magnetic material containing stack 20, metal cap 22 and metal-containing hard mask 24. The magnetic material containing stack 20 which can also be referred to as a MTJ structure includes, from bottom to top, a magnetic free material-containing layer, a tunnel barrier layer, and a magnetic reference material-containing layer. In the present application, the magnetic free material-containing layer forms a material interface with the SOT channel material layer 18L.

The magnetic free material-containing layer of the magnetic material containing stack 20 is composed of at least one magnetic material with a magnetization that can be changed in orientation relative to the magnetization orientation of the magnetic reference material in the magnetic material containing stack 20. Exemplary magnetic materials that can be used in providing the magnetic free material-containing layer of the magnetic material containing stack 20 include, but are not limited to, alloys and/or multilayers of cobalt, iron, alloys of cobalt-iron, nickel, alloys of nickel-iron, and alloys of cobalt-iron-boron. The magnetic free material-containing layer of the magnetic material containing stack 20 can have a thickness from 0.3 nm to 3 nm; although other thicknesses are possible and can be used as the thickness of the magnetic free material-containing layer of the magnetic material containing stack 20.

The tunnel barrier layer of the magnetic material containing stack 20 is composed of an insulator material and is formed at such a thickness as to provide an appropriate tunneling resistance. Exemplary materials for the tunnel barrier layer of the magnetic material containing stack 20 include, but are not limited to, magnesium oxide, aluminum oxide, titanium oxide, or materials of higher electrical tunnel conductance, such as semiconductors or low-bandgap insulators. The thickness tunnel barrier layer of the magnetic material containing stack 20 will depend on the material selected. In one example, tunnel barrier layer of the magnetic material containing stack 20 can have a thickness from 0.5 nm to 1.5 nm; although other thicknesses are possible as long as the thickness of tunnel barrier layer of the magnetic material containing stack 20 provides an appropriate tunneling resistance.

The magnetic reference-containing material layer of magnetic material containing stack 20 has a fixed magnetization. The magnetic reference-containing material layer of magnetic material containing stack 20 is composed of a metal or metal alloy that includes one or more metals exhibiting high spin polarization. In alternative embodiments, exemplary metals for the formation of the magnetic reference layer include iron, nickel, cobalt, chromium, boron, and manganese. Exemplary metal alloys may include the metals exemplified by the above. In another embodiment, the magnetic reference-containing material layer may be a multilayer arrangement having (1) a high spin polarization region formed from of a metal and/or metal alloy using the metals mentioned above, and (2) a region constructed of a material or materials that exhibit strong perpendicular magnetic anisotropy (strong PMA). Exemplary materials with strong PMA that may be used include a metal such as cobalt, nickel, platinum, palladium, iridium, or ruthenium, and may be arranged as alternating layers. The strong PMA region may also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys may be arranged as alternating layers. In one embodiment, combinations of these materials and regions may also be employed. Magnetic reference-containing material layer of magnetic material containing stack 20 can have a thickness from 0.3 nm to 3 nm; although other thicknesses are possible and can be used as the thickness of the magnetic reference-containing material layer of magnetic material containing stack 20.

The metal cap 22 is composed of a conductive metal-containing material such as, but not limited to, Ta, TaN, Ti, TiN, Ru, RuN, RuTa, RuTaN, Co, CoWP, CoN, or W. The metal-containing hard mask 24 is composed of a conductive metal-containing material that is compositionally different from the conductive metal-containing material that provides the metal cap 22. For example, and when Ru is used in providing the metal cap 22, the metal-containing hard mask 24 can be composed of TaN. In some embodiments, the metal-containing hard mask 24 can be omitted.

Each MTJ-containing fill structure, MTJ_2, which is formed can be located above one of the electrically conductive structures that are present in the interconnect dielectric layer 12 of the interconnect level 10. Each MTJ-containing fill structure, MTJ_2, and the active MTJ-containing structure, MTJ_1, can be formed by depositing a blanket layer of the magnetic material that provides the magnetic free material-containing layer, a blanket layer of the insulator that provides the tunnel barrier layer, a blanket layer or layers of magnetic material(s) that provides the magnetic reference material-containing layer, a blanket layer of conductive metal-containing material that provides the metal cap 22 and, in some embodiments, a blanket layer of conductive metal-containing material that provides the metal-containing hard mask 24. The depositing of these blanket layers includes, but is not limited to, CVD, PECVD, PVD, ALD (including plasma enhanced ALD) or sputtering. Following deposition, a first IBE patterning step is used to patterning the blanket layers into the MTJ-containing fill structures, MTJ_2, and the active MTJ-containing structure, MTJ_1. The first IBE patterning step includes a lithographic patterning process in which IBE is employed to etch through the blanket layers providing the MTJ-containing fill structures, MTJ_2, and the active MTJ-containing structure, MTJ_1, while stopping on a surface of the SOT channel material layer 18L.

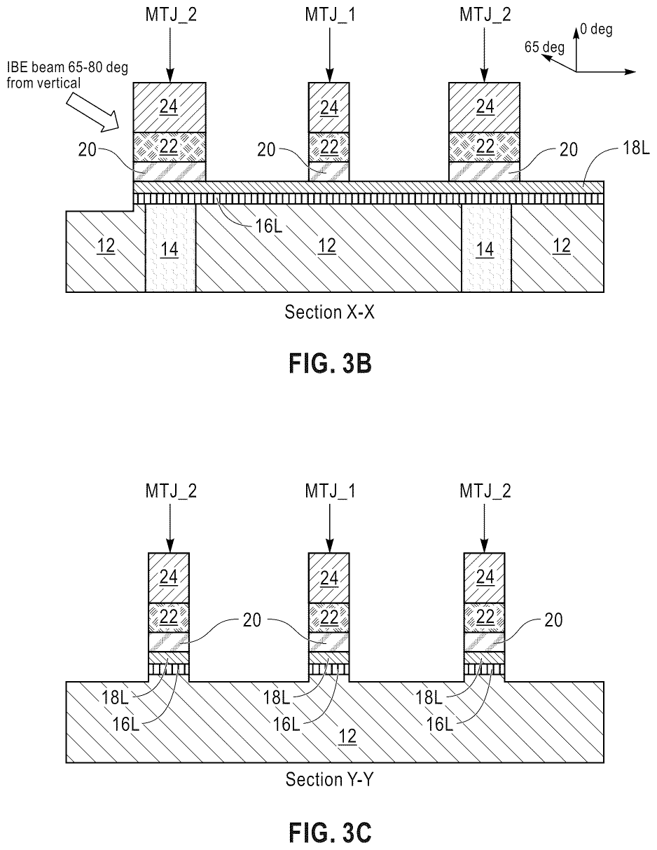

Referring now made to FIGS. 3A-3C, there are illustrated the exemplary structure shown in FIGS. 2A-2C, respectively, after performing a second IBE patterning step. The second IBE patterning step etches a portion of the SOT channel material layer 18L and, if present, a portion of the SOT seed material layer 16L with beam statically (i.e., no wafer rotation) aligned parallel to the X-direction at an IBE angle of 65 degrees to 80 degrees from vertical using the MTJ-containing fill structures, MTJ_2, as an etch mask. In some embodiments and as is illustrated in FIGS. 3B and 3C, the second IBE patterning process can also etch a portion of the interconnect dielectric layer 12. The MTJ-containing fill structures, MTJ_2, are designed to have a size (i.e., width) that is big enough in the X-direction such that during the second IBE patterning step the at least one electrically conductive structure 14 that is embedded in the interconnect dielectric layer 12 is protected. The MTJ-containing fill structures, MTJ_2, are designed to have a size (i.e., width) in the Y-direction that is substantially equal to the active MTJ-containing structure, MTJ_1, such that a SOT channel width which is substantially equal to the active MTJ-containing structure, MTJ_1, size (i.e., width) can be created. During the second IBE patterning step, the MTJ-containing fill structures, MTJ_2, height is sufficient to protect the SOT channel material layer 18L that is located between each MTJ-containing fill structure MTJ_2 and active MTJ-containing structure MTJ_1 combination.

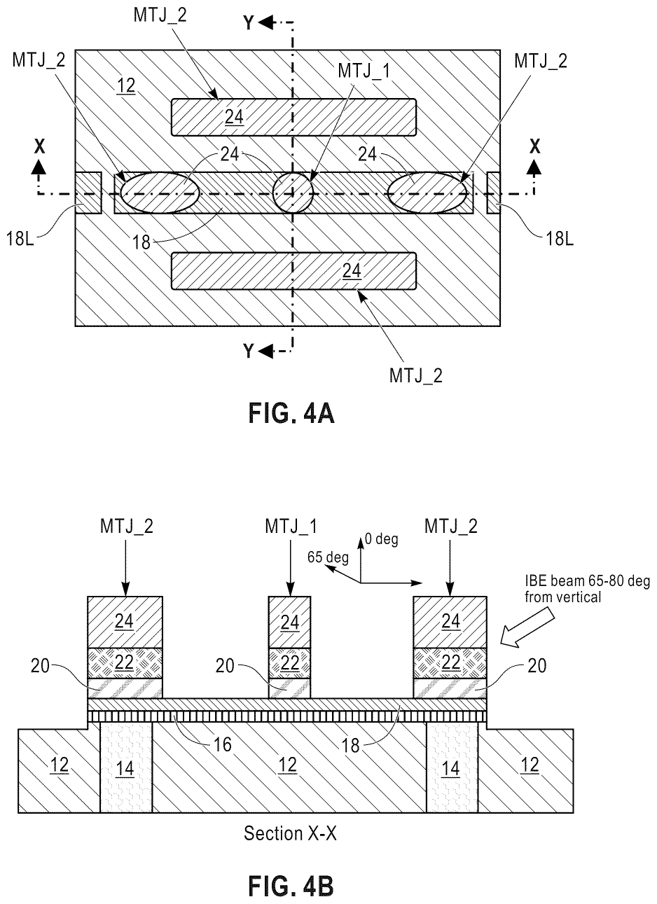

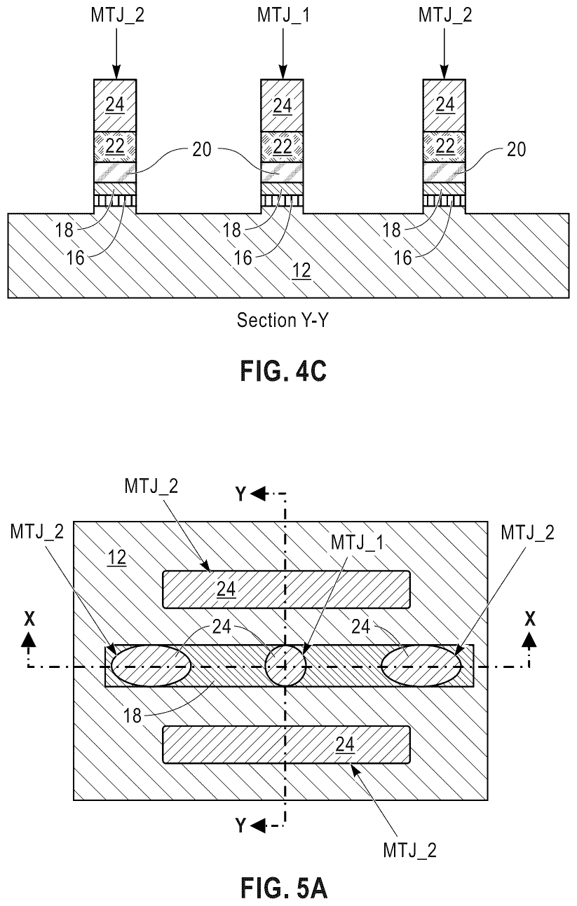

Referring now made to FIGS. 4A-4C, there are illustrated the exemplary structure shown in FIGS. 3A-3C, respectively, after performing a third IBE patterning step. The third IBE patterning step etches another portion of the SOT channel material layer 18L and, if present, another portion of the SOT seed material layer 16L with beam statically (i.e., no wafer rotation) aligned parallel to the X-direction at an IBE angle of 65 degrees to 80 degrees from vertical using the MTJ-containing fill structures, MTJ_2, as an etch mask, but with the wafer rotated 180 degrees relative to the second IBE patterning step. In some embodiments, the third IBE patterning process can also etch a portion of the interconnect dielectric layer 12. The MTJ-containing fill structures, MTJ_2, are designed to have a size (i.e., width) that is big enough in the X-direction such that during the third IBE patterning step the at least one electrically conductive structure 14 that is embedded in the interconnect dielectric layer 12 is protected. The MTJ-containing fill structures, MTJ_2, are designed to have a size (i.e., width) in the Y-direction that is substantially equal to the active MTJ-containing structure, MTJ_1, such that a channel width that is substantially equal to the active MTJ-containing structure, MTJ_1, size (i.e., width) can be created. During the third IBE patterning step, the MTJ-containing fill structures, MTJ_2, height is sufficient to protect the SOT channel layer 18 that is located between each MTJ-containing fill structure, MTJ_2, and active MTJ-containing structure, MTJ_1, combination. The third IBE patterning step forms the SOT channel layer 18 and the SOT seed layer 16. The SOT channel layer 18 is a remaining portion of the SOT channel material layer 18L that has been subjected to the second and third IBE patterning steps. The SOT seed layer 16 is a remaining portion of the SOT seed material layer 16L that has been subjected to the second and third IBE patterning steps.

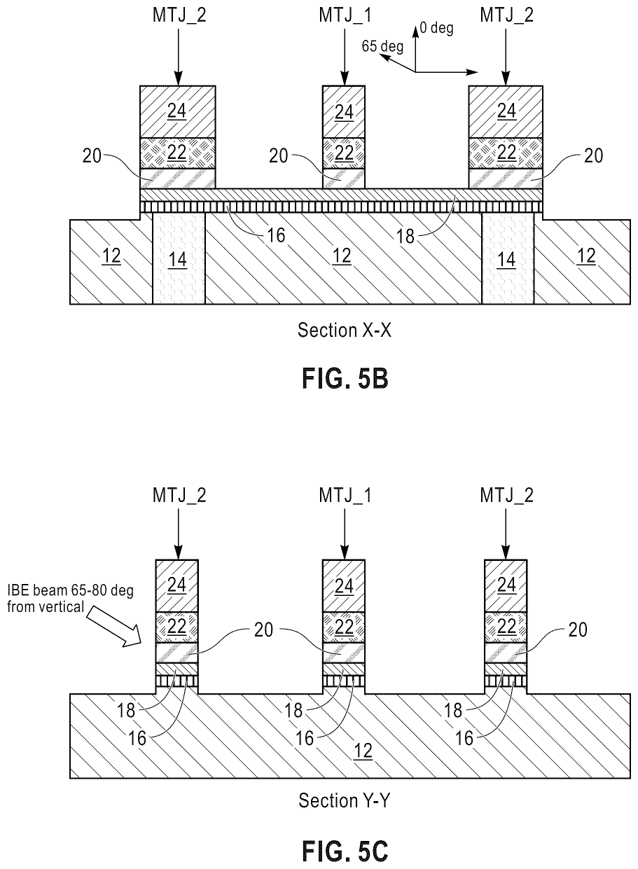

Referring now made to FIGS. 5A-5C, there are illustrated the exemplary structure shown in FIGS. 4A-4C, respectively, after performing a fourth IBE patterning step. The fourth IBE patterning step is optional and need not be performed in all embodiments. The fourth IBE patterning step is used to clean any SOT channel material layer 18L and, if present, SOT seed material layer 16L shadowed by neighboring devices during the second and third IBE patterning steps. When performed, the fourth IBE patterning step etches the SOT channel material layer 18L and, if present, the SOT seed material layer 16L that are shadowed with beam statically (i.e., no wafer rotation) aligned parallel to the Y-direction at an IBE angle of 65 degrees to 80 degrees from vertical using the MTJ-containing fill structures, MTJ_2, as an etch mask. The MTJ-containing fill structures, MTJ_2, height is sufficient to protect the SOT channel layer 18 that was formed by the third IBE patterning step.

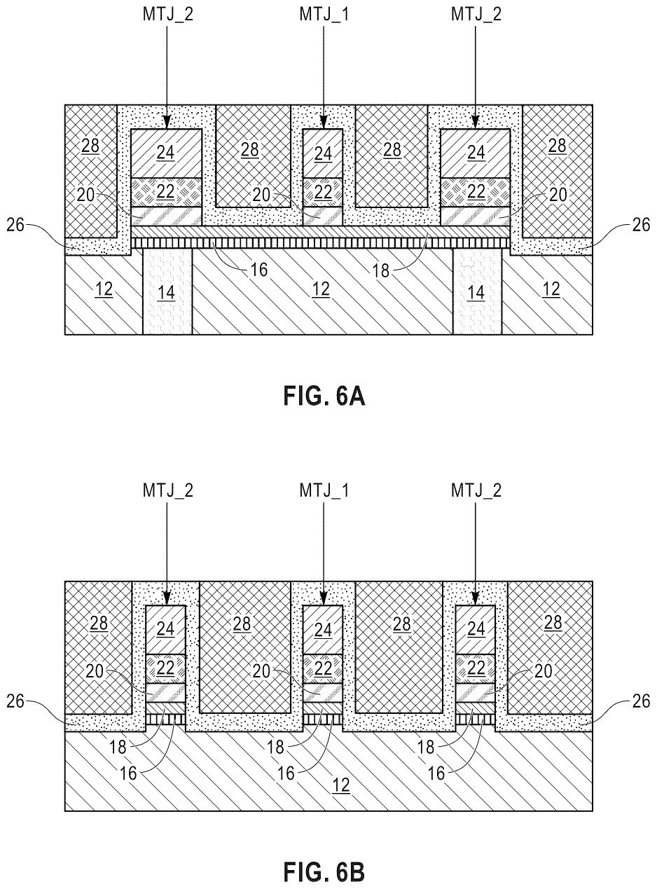

Referring now made to FIGS. 6A-6B, there are illustrated the exemplary structure shown in FIGS. 5B-5C, respectively, after performing a fifth IBE patterning step, forming a passivation liner 26, and forming a first ILD layer 28. The fifth IBE patterning step is performed to remove any material that might have been re-sputtered onto the sidewall of the active MTJ-containing structure, MTJ_1, during any of the previously performed IBE patterning steps. The fifth IBE patterning steps includes a 45 degree to 80 degree IBE angle with wafer rotation.

After performing this cleaning step, i.e., the fifth IBE patterning step, passivation liner 26 is formed. The passivation liner 26 can be composed of any dielectric material that can be used to encapsulation, and in some instances, passivate, the active MTJ-containing structure, MTJ_1. In some embodiments, the dielectric material that provides the passivation liner 26 includes atoms of silicon, carbon and hydrogen (i.e., a SiCH containing dielectric). In other embodiments, and in addition to atoms of carbon and hydrogen, the dielectric material that provides the passivation liner 26 can include atoms of at least one of nitrogen and oxygen. In still other embodiments, and in addition to atoms of silicon, nitrogen, carbon and hydrogen, the dielectric material that provides the passivation liner 26 can include atoms of boron. In one example, the dielectric material that provides the passivation liner 26 can be composed of an NBLOK dielectric material that contains atoms of silicon, carbon, hydrogen, nitrogen and oxygen. In alternative example, the dielectric material that provides the passivation liner 26 can be composed of a SiBCN dielectric material that contains atoms of silicon, boron, carbon, hydrogen, and nitrogen. The passivation liner 26 can be formed utilizing a deposition process such, as, for example, CVD, PECVD, ALD or spin-on coating.

The passivation liner 26 is formed on a topmost surface and along a sidewall of the active MTJ-containing structure, MTJ_1, and on a topmost surface and along a sidewall of each MTJ-containing fill structures, MTJ_2. The passivation liner 26 is formed on a topmost surface of the SOT channel layer 18, along a sidewall of both the SOT channel layer 18 and the SOT seed layer 16, and on top of a surface (typically a sub-surface) of the interconnect dielectric layer 12. The term “sub-surface” denotes a surface of a material that is located between a topmost surface and bottommost surface of the material.

After forming the passivation liner 26, first ILD layer 28 is formed on the passivation liner 26. The first ILD layer 28 is composed of an interconnect dielectric material including, for example, silicon oxide (SiOₓ), silicon nitride, undoped silicate glass (USG), fluorosilicate glass (FSG), borophosphosilicate glass (BPSG), a spin-on low-k dielectric, a chemical vapor deposition (CVD) low-k dielectric, or any combination thereof. The first ILD layer 28 can be formed by a deposition process such as, for example, CVD, PECVD or spin-on coating. In some embodiments, a planarization process such as, for example, CMP or grinding can be used to reveal the passivation liner 26 that is located on top of the active MTJ-containing structure, MTJ_1, and on top of each MTJ-containing fill structure, MTJ_2.

Referring now made to FIGS. 7A-7B, there are illustrated the exemplary structure shown in FIGS. 6A-6B, respectively, after forming a metal structure 32 in contact with at least a topmost surface the active MTJ-containing structure, MTJ_1. It is noted that FIG. 7B is the same as FIG. 1 described above. The metal structure 32 is composed of an electrically metal or electrically conductive metal alloy as defined above with respect to the at least one electrically conductive structure 14. In some embodiments, a diffusion barrier liner (composed of a diffusion barrier material as defined above) can be located along a sidewall and a bottommost surface of the metal structure 32. In embodiments in which no diffusion barrier liner is located along the bottommost surface of the metal structure 32, the metal structure 32 is in direct physical and electrical contact with the active MTJ-containing structure, MTJ_1. In embodiments in which a diffusion liner is present along the bottommost surface of the metal structure 32, the metal structure 32 is in electrically contact with the active MTJ-containing structure, MTJ_1, through the diffusion barrier liner that separates the metal structure 32 from the active MTJ-containing structure, MTJ_1. The metal structure 32 contacts a topmost surface and, in some embodiments, a sidewall surface of the active MTJ-containing structure, MTJ_1. Notably, the metal structure 32 contacts a topmost surface and, in some embodiments, a sidewall surface of the electrode (e.g., the metal-containing hard mask 24) of the active MTJ-containing structure, MTJ_1.

As is illustrated in FIG. 7A, the metal structure 32 is partially embedded in a second ILD layer 30. The second ILD layer 30 is composed of an interconnect dielectric material including those mentioned above for the first ILD layer 28. The interconnect dielectric material that provides the second ILD layer 30 can be compositionally the same or compositionally different from the interconnect dielectric material that provides the first ILD layer 28.

The structure shown in FIGS. 7A-7B can be formed by first depositing the interconnect dielectric material that provides the second ILD layer 30. After depositing the interconnect dielectric material that provides the second ILD layer 30, an opening can be formed to physically expose a surface of the active MTJ-containing structure, MTJ_1. The opening can be formed by lithography and etching in which the etching removes at least a portion of the second ILD layer 30 and the passivation liner 26 that is located on a topmost surface of the active MTJ-containing structure, MTJ_1; this opening does not expose any of the MTJ-containing fill structures, MTJ_2, that are neighbors to MTJ_1 in the X direction. The etch used in forming the opening can also remove a portion of the first ILD layer 28 and a portion of the passivation liner 26 that is located on an upper portion of the sidewall of the active MTJ-containing structure, MTJ_1.

Next, and if present, a layer of diffusion barrier material can be formed in the opening and on top of the second ILD layer 30. The forming of the layer of diffusion barrier material includes a deposition process such as, for example, CVD, PECVD, PVD or ALD. The layer of diffusion barrier material does not fill in an entirety of the opening. Next, one of the above mentioned electrically conductive materials (e.g., Cu) is then deposited in the opening and on top of the layer of diffusion barrier material (if the same is present). The deposition of the electrically conductive material can include CVD, PECVD, PVD, ALD, sputtering or plating. A planarization process such as, for example, CMP, is then performed to remove the layer of diffusion barrier material (if the same is present) and the electrically conductive material that is formed outside of the opening and on top of the second ILD layer 30. The electrically conductive material and, if present, the layer of diffusion barrier material remain in the opening after the planarization process. The electrically conductive material that remains in the opening provides metal structure 32 and, if present, the diffusion barrier material layer that remains in the opening provides the diffusion barrier liner (not shown in the drawings of the present application). In embodiments of the present application, the metal structure 32 has a topmost surface that is substantially coplanar with at least a topmost surface of the second ILD layer 30; if a diffusion barrier liner is present, the topmost surface of the metal structure 32 can be substantially coplanar with a topmost surface of the diffusion barrier liner as well as with a topmost surface of the second ILD layer 30.

Referring now to FIG. 8, there is illustrated (through a top down view) another exemplary SOT MRAM device in accordance with an embodiment of the present application. In the embodiment illustrated in FIG. 8 there is no need for MTJ-containing fill structures, MTJ_2, in the Y-direction, if the X-direction separation between columns of SOT MRAM devices is made larger because there is no need to do static IBE in the Y-direction.

Notably, FIGS. 1, 7A-7B and 8 illustrate a SOT MRAM device in accordance with an embodiment of the present application. The SOT MRAM device include in each of FIGS. 1, 7A-7B and 8 includes active MTJ-containing structure, MTJ_1, located on SOT channel layer 18, where the active MTJ-containing structure, MTJ_1, has a width (in the Y direction) that is substantially equal to a width (in the same Y-direction) of the SOT channel layer 18.

More specifically, and is illustrated in FIGS. 1 and 7A-7B, the SOT MRAM device includes interconnect level 10 including at least one electrically conductive structure 14 embedded in interconnect dielectric layer 12, SOT channel layer 18 located above the interconnect level 10, active MTJ-containing structure, MTJ_1, located on the SOT channel layer 18, where the active MTJ-containing structure, MTJ_1, has a width (in the Y-direction) that is substantially equal to a width (in the Y-direction) of the SOT channel layer 18, passivation liner 26 present along a sidewall of the active MTJ-containing structure, MTJ_1, and along sidewall of the SOT channel layer 18, where the passivation liner 26 extends below a bottommost surface of the SOT channel layer 18 and is present on a surface of the interconnect dielectric layer 12 of the interconnect level 10, and metal structure 32 in contact with the active MTJ-containing structure, MTJ_1.

Although FIGS. 1, 7A and 7B illustrate a single active MTJ-containing structure, MTJ_1, a plurality of active MTJ-containing structure, MTJ_1, arranged in rows and columns can be formed in which each active MTJ-containing structure, MTJ_1, of the plurality of active MTJ-containing structure, MTJ_1, has a width that is substantially equal to a width of the SOT channel layer 18.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A spin-orbit torque magnetoresistive random access memory (SOT MRAM) device comprising:
an active magnetic tunnel junction (MTJ)-containing structure located on a SOT channel layer, wherein the active MTJ-containing structure has a width that is substantially equal to a width of the SOT channel layer.

2. The SOT MRAM device of claim 1, wherein the active MTJ-containing structure comprises an electrode and a magnetic material containing stack of, from bottom to top, a magnetic free material-containing layer, a tunnel barrier layer, and a magnetic reference material-containing layer, wherein the magnetic free material-containing layer of the magnetic material containing stack forms a material interface with the SOT channel layer and the electrode is located on top of the magnetic material containing stack.

3. The SOT MRAM device of claim 1, further comprising a SOT seed layer located beneath the SOT channel layer, wherein the SOT seed layer has a width that substantially matches the width of both the SOT channel layer and the active MTJ-containing structure.

4. The SOT MRAM device of claim 1, further comprising an interconnect level located beneath the SOT channel layer, wherein the interconnect level comprises at least one electrically conductive structure embedded in an interconnect dielectric layer.

5. The SOT MRAM device of claim 1, further comprising a passivation liner present along a sidewall of the active MTJ-containing structure and along sidewall of the SOT channel layer, wherein the passivation liner extends below a bottommost surface of the SOT channel layer.

6. The SOT MRAM device of claim 1, further comprising a metal structure in contact with the active MTJ-containing structure.

7. The SOT MRAM device of claim 6, wherein the metal structure contacts a topmost surface of the active MTJ-containing structure.

8. The SOT MRAM device of claim 6, wherein the metal structure contacts a topmost surface and a sidewall surface of the active MTJ-containing structure.

9. The SOT MRAM device of claim 1, further comprising MTJ-containing fill structures located along an X-direction and a Y-direction of the device and surrounding the active MTJ structure.

10. The SOT MRAM device of claim 1, further comprising MTJ-containing fill structures located along an X-direction of the device, and present adjacent to the active MTJ-containing structure.

11. A spin-orbit torque magnetoresistive random access memory (SOT MRAM) device comprising:
an interconnect level comprising at least one electrically conductive structure embedded in an interconnect dielectric layer;
a SOT channel layer located above the interconnect level;
an active magnetic tunnel junction (MTJ)-containing structure located on the SOT channel layer, wherein the active MTJ-containing structure has a width that is substantially equal to a width of the SOT channel layer;
a passivation liner present along a sidewall of the active MTJ-containing structure and along sidewall of the SOT channel layer, wherein the passivation liner extends below a bottommost surface of the SOT channel layer and is present on a surface of the interconnect dielectric layer of the interconnect level; and
a metal structure in contact with the active MTJ-containing structure.

12. The SOT MRAM device of claim 11, wherein the active MTJ-containing structure comprises an electrode and a magnetic material containing stack of, from bottom to top, a magnetic free material-containing layer, a tunnel barrier layer, and a magnetic reference material-containing layer, wherein the magnetic free material-containing layer of the magnetic material containing stack forms a material interface with the SOT channel layer and the electrode is located on top of the magnetic material containing stack.

13. The SOT MRAM device of claim 11, further comprising a SOT seed layer located between the SOT channel layer and the interconnect level, wherein the SOT seed layer has a width that substantially matches the width of both the SOT channel layer and the active MTJ-containing structure.

14. The SOT MRAM device of claim 11, wherein the metal structure contacts a topmost surface of the active MTJ-containing structure.

15. The SOT MRAM device of claim 11, wherein the metal structure contacts a topmost surface and a sidewall surface of the active MTJ-containing structure.

16. The SOT MRAM device of claim 11, further comprising MTJ-containing fill structures located along a X-direction and a Y-direction of the device and surrounding the active MTJ-containing structure.

17. The SOT MRAM device of claim 11, further comprising MTJ-containing fill structures located along a X-direction of the device, and present adjacent to the active MTJ-containing structure.
